(19) United States
(12) Patent Application Publication
(10) Pub. No.: US 2007/0267756 A1
(43) Pub. Date: Nov. 22, 2007

(54) Integrated circuit package and multi-layer lead frame utilized

(75) Inventors: I-Hsin Mao, Tainan (TW); Ya-Chi Chen, Tainan (TW); Chun-Ying Lin, Tainan (TW); Yu-Ren Chen, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/543,052

(22) Filed: Oct. 5, 2006

(30) Foreign Application Priority Data
May 16, 2006 (CN) 095117275

(51) Int. Cl. H01L 23/52

(52) U.S. Cl. 257/777

(57) ABSTRACT

An IC package with a defined wire-bonding region primarily comprises a multi-layer lead frame with a plurality of leads, a chip, a plurality of bonding wires within the wire-bonding region, and at least an electrical transition component outside the wire-bonding region. At least a transition finger is carried on one of the lead and is electrically isolated from the corresponding carrying lead without covering inner end of the carrying lead. The parts of the electrical transition component electrically connects the transition finger to another lead that is not directly below the transition finger to reduce the crossings of the bonding wires or to increase the vertical distances between the bonding wires at the crossings to avoid electrical shorts between the bonding wires during encapsulation.

### FIELD OF THE INVENTION

The present invention relates to an IC package and a lead frame for the package, and more particularly, to an IC package with a multi-layer lead frame.

### BACKGROUND OF THE INVENTION

In the conventional packaging technologies, lead frames or wiring substrates can be chosen as chip carriers where lead frames have the advantages of lower cost. However, the leads of a lead frame can not disposed in more than two rows nor in arrays so that IC packages using lead frames as chip carriers are not suitable for ICs with complicated design. The wiring substrates are more suitable for high-end ICs using plated through holes and multi-layer circuit design to dispose the inner fingers in staggers and the outer pads in arrays on two sides of a substrate, however, the cost of substrate is high.

As shown in FIGS. 1 and 2, a conventional IC package 100 comprises a lead frame with leads 111, a chip 120, a plurality of bonding wires 130, and an encapsulant 140. A conventional lead frame is a single-layer metal film structure having a die pad 112. The chip 120 is attached to the die pad 112. Then, the plurality of bonding pads 121 of the chip 120 are electrically connected to the top surfaces 113 of the leads 111 by a plurality of bonding wires 130. The encapsulant 140 encapsulates the chip, the bonding wires 130, and the leads 111. The bottom surface 114 of the leads 111 can be exposed from the encapsulant 140. However, when the arrangement of the bonding pads 121 of the chip 120 is different from the arrangement of the leads 111, then, some bonding wires 130 have to vertically cross each other after wire bonding processes, as the first bonding wire 131 and the second bonding wire 132 shown in FIG. 2. During wire bonding processes, the first bonding wire 131 and the second bonding wire 132 will at least vertically cross each other at one crossing 133 with a very small gap between the two bonding wires. In the worst case, the first bonding wire 131 contacts with the second bonding wire 132 after wire bonding processes. Moreover, there is a risk of electrical shorts between the first bonding wire 131 and the second bonding wire 132 during the formation of the encapsulant 140. Therefore, a single-layer lead frame is not suitable for complicated wire-bonding.

### SUMMARY OF THE INVENTION

The main purpose of the present invention is to provide an IC package with a multi-layer lead frame where a multi-layer lead frame and at least a electrical transition component outside a wire-bonding region are implemented to avoid electrical shorts between the bonding wires due to decrease in the crossings of the high-density bonding wires and to increase the applications of lead frames as chip carriers in IC packages.

The second purpose of the present invention is to provide an IC package with a multi-layer lead frame where electrically-isolated transition fingers on the lead frame are implemented to increase the locations of electrical connections for electrical transition component from the bonding pads of a chip to the leads of a lead frame.

According to the present invention, an IC package primarily comprises a multi-layer lead frame, a chip, a plurality of bonding wires, and at least an electrical transition component where the multi-layer lead frame has a plurality of leads carrying with at least one transition finger. The transition finger is disposed on one of the leads and is electrically isolated with the corresponding carrying lead without covering the inner end of the corresponding carrying lead. The chip has a plurality of bonding pads. At least a wire-bonding region is defined in the IC package to cover the bonding pads, the inner ends of the leads and the bonding wires. The bonding pads of the chip are electrically connected to the inner ends of the leads by the bonding wires within the wire-bonding region. At least parts of the electrical transition component are formed outside the wire-bonding region to electrically connect the transition finger to another one of the leads except the carrying lead directly under the transition finger.

### DESCRIPTION OF THE DRAWINGS

FIG. 1 shows a cross sectional view of a conventional IC package.

FIG. 2 shows a top view of the conventional IC package before encapsulation.

FIG. 3 shows a cross sectional view of an IC package according to the first embodiment of the present embodiment.

FIG. 4 shows a top view of the IC package before encapsulation according to the first embodiment of the present embodiment.

FIG. 5 shows a partial three-dimensional view of the IC package according to the first embodiment of the present embodiment.

FIG. 6 shows a partial three-dimensional view of an IC package according to the second embodiment of the present embodiment.

FIG. 7 shows a cross sectional view of an IC package according to the third embodiment of the present embodiment.

FIG. 8 shows a partial three-dimensional view of the IC package according to the third embodiment of the present embodiment.

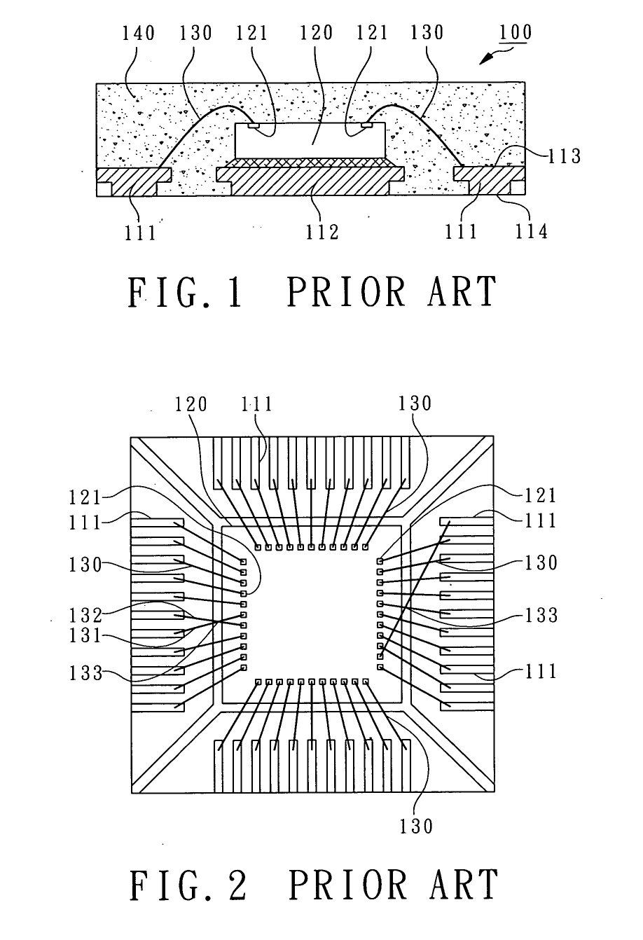

### DETAIL DESCRIPTION OF THE INVENTION

Please refer to the attached drawings, the present invention will be described by means of embodiment(s) below.

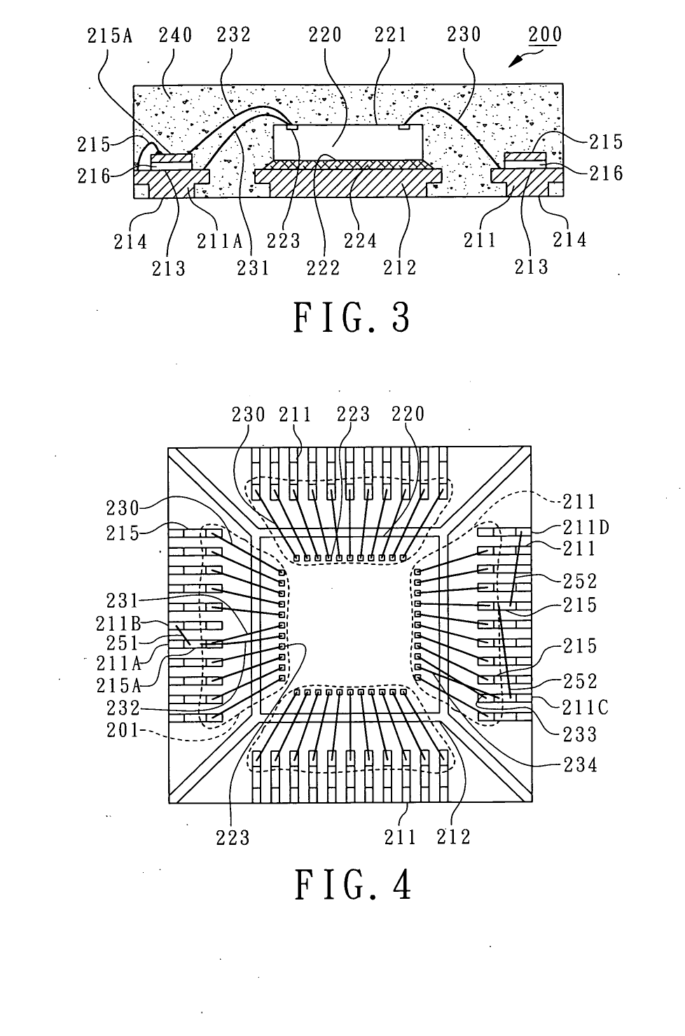

An IC package is revealed in FIGS. 3, 4, and 5 according to the first embodiment of the present invention. The IC package 200 primarily comprises a multi-layer lead frame, a chip 220, a plurality of bonding wires 230, and at least an electrical transition component 251, 252. The multi-layer lead frame has a plurality of leads 211 and at least a transition finger 215 or transition island. Each lead 211 has a top surface 213 and a bottom surface 214 where the transition finger 215 is carried on one of the top surface 213 of the leads 211. In the present embodiment, each lead 211 carries a transition finger 215 on its top surface 213. Moreover, the transition fingers 215 are electrically isolated from the corresponding leads 211 directly under the transition fingers 215 without covering inner ends of the corresponding carrying leads 211. In this embodiment, the carrying lead 211 is a first lead 21 1A as shown in FIG. 4. Therein, the inner end is one end of the carrying lead 211 toward the chip 220 and the outer end is the other end of the carrying lead 211 far away from the chip 220. The transition fingers 215 are electrically conductive and are made of copper or other metals. In the present embodiment, an isolation layer 216 is formed between the transition fingers 215 and the corresponding leads 211 to electrically isolate the transition fingers 215 directly above and the corresponding leads 211 directly below. In the present embodiment, the multi-layer lead frame further has a die pad 212 for attaching the chip 220, however, the die pad 212 is not necessary. For example, the IC package 200 can be a bare-die package by using a temporary adhesive tape, not shown in the figure, to fix back surface of the chip during packaging processes where the temporary adhesive tape is removed after encapsulation to expose the back surface 222 of the chip 220.

The chip 220 has an active surface 221, a corresponding back surface 222, and a plurality of bonding pads 223 on the active surface 221 where the bonding pads 223 are formed at the center or at the peripheries of the active surface 221. Alternatively, bumps may be disposed on the bonding pads 223. The back surface 222 of the chip 220 is attached to the die pad 212 by a die-attaching material 224.

Those bonding wires 230 without the needs of wire crossings are bonded from the bonding pads 223 to the top surface of the inner ends of the corresponding leads 211. The bonding wires 230 are normally gold wires. At least a wire-bonding region 201 is defined inside the IC package 200 to define a formation area of the bonding wires 230 connecting the chip 220 and the leads 211. Furthermore, the wire-bonding region 201 covers the bonding pads 223 and the inner ends of the leads 211. One end of the transition fingers 215 may be extended into the wire-bonding region 201. As shown in FIG. 4, there are four wire-bonding regions 201 located at the four sides of the chip 220 according to the present embodiment.

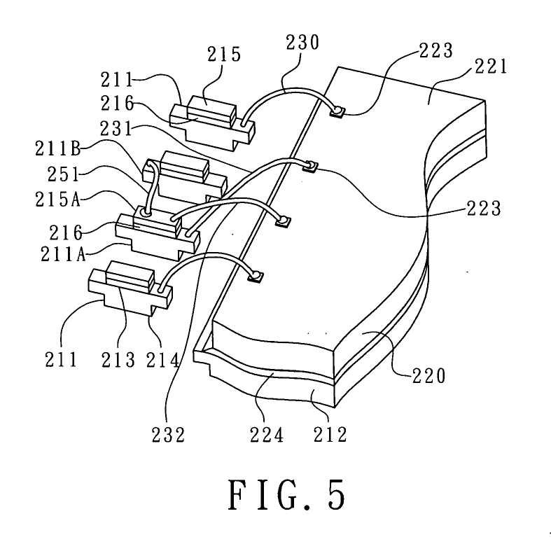

Those bonding wires 230 with the needs of wire crossings are shown in FIGS. 4 and 5. In a conventional design, some of the bonding wires 230 connecting the first lead 211A and for the second lead 211B are supposed to cross each other, so as some of the bonding wires 230 connecting the third lead 211C and the fourth lead 211D. As shown in FIG. 5, in the present embodiment, the first bonding wire 231 connects the inner end of the first lead 211A which is not covered by the transition finger 215A to the corresponding bonding pad 223 at the upper right position. The second bonding wire 232 is altered to connect from one of the bonding pad 223 at the straight right position to the transition finger 215A of the first lead 211 A, not to the second lead 211B. Therefore, as shown in FIG. 4, the crossings of the first bonding wire 231 and the second bonding wire 232 can be reduced or eliminated. Even the crossings can not be avoided, the vertical distance between the first bonding wire 231 and the second bonding wire 232 will be greater than the thickness of the transition finger 215, i.e., the shortest vertical distance between the first bonding wire 231 and the second bonding wire 232 is increased and the electrical shorts between the first bonding wire 231 and the second bonding wire 232 during encapsulation can also be avoided. In the conventional IC package, the vertical distance between the crossed bonding wires is very small. Even with some minor sweeping of the bonding wires during encapsulaiton, electrical shorts are not the results. Furthermore, as shown in FIG. 5, the transition finger 215A on the first lead 211A is electrically connected to the outer end of the second lead 211B, which is another lead 211 not directly under the transition finger 215A, by the electrical transition component 251 so that one of the bonding pads 223 of the chip can be electrically connected to the second lead 211B by the second bonding wire 232, the transition finger 215A on the first lead 211A, and the electrical transition component 251. In this embodiment, the electrical transition component 251 is completely formed outside the wire-bonding region 201. When the distance between the first lead 211A and the second lead 211B is too long, then the transition finger 215A of the first lead 211A can be bonded to the other transition fingers 215 as middle bonding by using a plurality of electrical transition component 251, not shown in the figure, and eventually can be electrically connected to the second lead 211B. Preferably, the electrical transition component 251 is a bonding wire and is bonded with the bonding wires 230 in the same wire-bonding step to simplify packaging processes. As shown in FIG. 5, the transition finger 215 has a width approximately equal to that of the corresponding carrying lead 211 directly below but shorter than the carrying lead 211 so as not to cover the inner end of the top surface 213 of the lead 211. In the present embodiment, the transition finger 215 without covering the outer end of the top surface 213 of the lead 211 is acceptable so that the outer end can be used for the bonding of the electrical transition component 251. Accordingly, the encapsulant 240 will completely encapsulate the transition fingers 215 and the isolation layers 216. Therefore, one end of the electrical transition component 251 can be bonded to the outer end of the top surface 213 of the second lead 211B so that the electrical transition component 251 is located at the edges or corners of the IC package 200 but not within the wire-bonding regions, then the design of the layout of the bonding wires 230 can be simplified.

Similarly, as shown in FIG. 4, the third bonding wire 233 should connect the third lead 211C and the fourth bonding wire 234 should connect the fourth lead 211D in a conventional layout. The fourth bonding wire 234 is altered to connect the transition finger 215 on the third lead 211C. The transition finger 215 on the third lead 211C is electrically connected to the fourth lead 211D by using at least one electrical transition component 252. If the distance between the third lead 211C and the fourth lead 211D is too long, the bonding pad 223 can be electrically connected to the fourth lead 211D first by the fourth bonding wire 234 to the transition finger 215 on the third lead 211C, then by an electrical transition component 251 electrically connect to other transition fingers 215, then bonded to the fourth lead 211D, which is another lead 211 not including the corresponding carrying lead 211C. Moreover, the electrical transition component 252 is located outside the defined wire-bonding region without complicating the layout of the bonding wires 230. Therefore, the vertical crossings of the fourth bonding wire 234 with the other bonding wires have been greatly reduced and the vertical distance between the third bonding wire 233 and the fourth bonding wire 234 is increased so that the electrical shorts between the fourth bonding wire 234 and the other bonding wires can be avoided.

Moreover, the IC package 200 further comprises an encapsulant 240 to encapsulate parts of the chip 220 such as the active surface 221 and the sidewalls, parts of the multi-layer lead frame including the top surface 213 and the sidewalls of the leads 211, the bonding wires 230, and the electrical transition component 251, 252. The encapsulant 240 is formed by molding which may be a thermal-setting plastic, inorganic fillers, dyes, etc. In the present embodiment, referring to FIG. 3 again, the leads 211 have a plurality of outer ends approximately aligned with the sides of the encapsulant 240, to form a leadless IC package such as QFN, SON, LGA, packages or contacting cards which use the bottom surface 214 of the leads 211 as external terminals. In various applications, the outer ends of the leads 211 may be slightly embedded in the encapsulant 240, or slightly protrude from the sides of the encapsulant 240 to form different kinds of leadless IC packages. In the first embodiment of the present invention, as shown in FIG. 4, the leads 211 can be disposed at the bottom peripheries of the IC package 200 to form a QFN package. The leads 211 can be disposed at two sides of the bottom of the IC package 200 to form an SON package. The leads can be disposed at the bottom of the IC package 200 to form a LGA package. The leads can also be metal pads with large areas to form a contacting card.

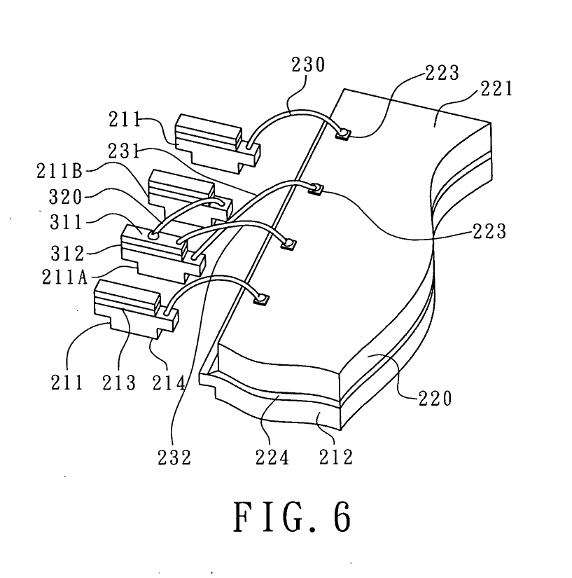

As shown in FIG. 6, the IC package revealed in the second embodiment is about the same as the IC package revealed in the first embodiment, therefore, the numbers of primary components in the figures will be the same as the first embodiment, such as a chip 220, a multi-layer lead frame with a plurality of leads 211 and a die pad 212, a first bonding wire 231, and a second bonding wire 232. A plurality of transition fingers 311 are carried on the leads 211 where the transition fingers 311 are electrically isolated from the corresponding lead 211 directly below. In the present embodiment, the transition finger 311 covers most of the top surface 213 of the leads 211 including the outer end except the inner end on the top surface 213 of the leads 211. One end of an electrical transition component 320 is bonded to the transition finger 311 on the first lead 211A and the other end of the electrical transition component 320 to the inner end of the second lead 211B. Therefore, parts of the electrical transition component 320 can be extended into the wire-bonding region.

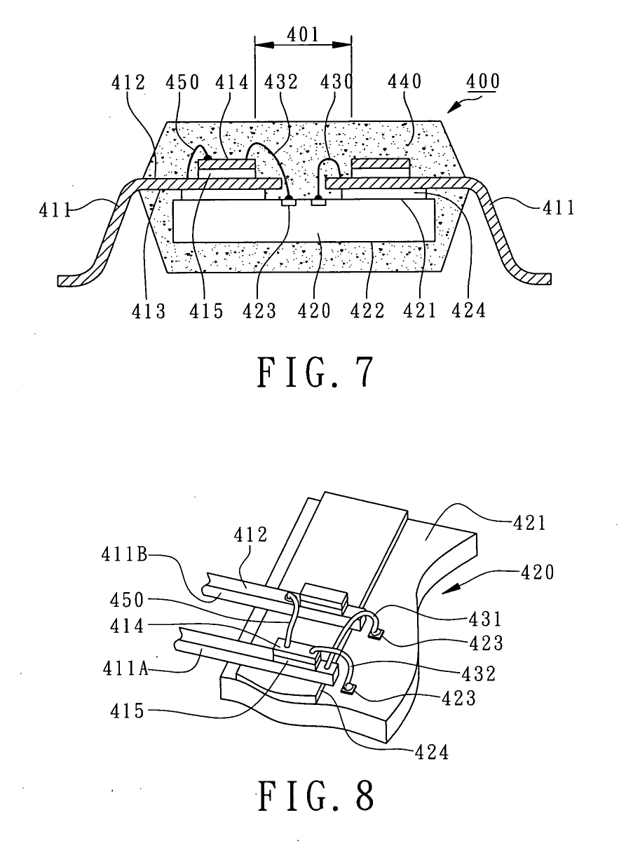

The third embodiment of the present invention is to describe another IC package as shown in FIGS. 7 and 8, which is not a leadless IC package. An IC package 400 primarily comprises a multi-layer lead frame, a chip 420, a plurality of bonding wires 430, at least an electrical transition component 450, and an encapsulant 440 where the multi-layer lead frame has a plurality of leads 411 and at least a transition finger 414 carried thereon. In the present embodiment, a plurality of transition fingers 414 are carried on the top surfaces 412 of the leads 411 respectively. The transition fingers 414 and the corresponding leads 411 directly below are electrically isolated by an insulation layer 415 without covering the inner end of the top surface 412 of the corresponding lead 411. The active surface 421 of the chip 420 is attached to the inner end of the bottom surface 413 of the leads 411 with an adhesive tape or a B-stage die-attaching material 424. The outer end of the leads 411 are outwardly extended from the sides of the encapsulant 440 and are formed into gull shapes, J shapes, or I shapes as external terminals for surface mounting.

The chip 420 has a plurality of bonding pads 423 forming at the center of the active surface 421 of the chip 420. Those bonding wires 430 without the needs of wire crossings are bonded from the bonding pads 423 of the chip 420 to the inner ends of the leads 411. As shown in FIG. 7, a wire-bonding region 401 is defined inside the IC package 400 where the wire-bonding region 401 covers the bonding wires 430, the bonding pads 423, the inner ends of the lead 411, and parts of the transition fingers 414. Those bonding wires 230 with the needs of wire crossings such as the first lead 411A and the second lead 411B, as shown in FIG. 8, the first bonding wire 431 is bonded from one of the bonding pads 423 of the chip 420 to the inner end of the top surface 412 of the first lead 411A and the second bonding wire 432 is bonded from another bonding pad 423 of the chip 420 to the transition finger 414 of the first lead 411A, then electrical connection from the transition finger 414 of the first lead 411A to the outer end of the lead 411B by an electrical transition component 450. Therefore, the vertical crossings of the first bonding wire 431 and the second bonding wire 432 are eliminated or the vertical distance between the first bonding wire 431 and the second bonding wire 432 is increased to avoid electrical shorts between the first bonding wire 431 and the second bonding wire 432 during encapsulation.

Preferably, the electrical transition component 450 is completely formed outside the wire-bonding region 401 so that the design of the layout of the bonding wires 430 can be simplified. In the present embodiment, the electrical transition component 450 is a bonding wire. The encapsulant 440 encapsulates the active surface 421 and the back surface 422 of the chip 420, the inner ends of the leads 411 of the multi-layer lead frame, the bonding wires 430, and the electrical transition component 450.

The above description of embodiments of this invention is intended to be illustrative and not limiting. Other embodiments of this invention will be obvious to those skilled in the art in view of the above disclosure.

What is claimed is:

1. An IC package with at least a defined wire-bonding region, comprising:
a lead frame having a plurality of leads and at least a transition finger, wherein the transition finger is carried on one of the leads and is electrically isolated from the corresponding lead directly below without covering an inner end of the carrying lead;
a chip having a plurality of bonding pads, wherein the wire-bonding region covers the bonding pads and the inner ends of the leads;
a plurality of bonding wires formed within the wire-bonding region and connecting the bonding pads of the chip to the inner ends of the leads; and
at least an electrical transition component having at least a part outside the wire-bonding region to electrically connect the transition finger to another lead except the carrying lead directly under the transition finger.

2. The IC package of claim 1, the electrical transition component is completely formed outside the wire-bonding region.

3. The IC package of claim 2, wherein the electrical transition component is located at the edges or at the corners of the IC package.

4. The IC package of claim 1, wherein the electrical transition component is a bonding wire.

5. The IC package claim 1, wherein parts of the electrical transition component are extended into the wire-bonding region.

6. The IC package claim 1, wherein one end of the transition finger is extended into the wire-bonding region.

7. The IC package of claim 1, further comprising an isolation layer formed between the transition finger and the corresponding carrying lead.

8. The IC package of claim 1, wherein the transition finger is as equally wide as the corresponding carrying lead but shorter than said lead.

9. The IC package of claim 1, wherein the transition finger does not cover an outer end of the corresponding carrying lead.

10. The IC package of claim 1, further comprising an encapsulant encapsulating at least parts of the chip, parts of the lead frame, the bonding wires, and the electrical transition component.

11. The IC package of claim 10, wherein the leads have a plurality of outer ends aligned with the sides of the encapsulant to form a leadless IC package.

12. A multi-layer lead frame for IC packages, comprises:
a plurality of leads;
at least a transition finger carried on one of the leads without covering an inner end of the carrying lead; and
at least an isolation layer formed between the transition finger and the corresponding lead to electrically isolate the transition finger and the corresponding carrying lead.

13. The multi-layer lead frame of claim 12, wherein the transition finger does not cover an outer end of the corresponding carrying lead.

14. The multi-layer lead frame of claim 12, wherein the transition finger is as equally wide as the corresponding carrying lead but shorter than said lead.
